(19) United States
(12) Patent Application Publication
(10) Pub. No.: US 2024/0412767 A1
(43) Pub. Date: Dec. 12, 2024

(54) MULTI-BIT CELL AND MULTI-BIT CELL ARRAY INCLUDING THE SAME

(71) Applicant: SAMSUNG ELECTRONICS CO., LTD., SUWON-SI, GYEONGGI-DO (KR)

(72) Inventors: CHANHEE PARK, Suwon-si, Gyeonggi-do (KR); HYUNCHUL HWANG, Suwon-si, Gyeonggi-do (KR)

(21) Appl. No.: 18/437,394

(22) Filed: Feb. 9, 2024

(30) Foreign Application Priority Data
Apr. 5, 2023 (KR) 10-2023-0044977
Jun. 21, 2023 (KR) 10-2023-0079448

(51) Int. Cl. G11C 7/22; G11C 7/10

(52) U.S. Cl. CPC G11C 7/222; G11C 7/1012; G11C 7/1057

(57) ABSTRACT

A multi-bit cell includes a plurality of memory cells arranged in an M×N array M rows and N columns, a plurality of first clock lines, a plurality of second clock, and a plurality of data lines. Each of the first clock lines is commonly connected to the memory cells of a corresponding one of the N columns. Each of the second clock lines is commonly connected to the memory cells of a corresponding one of the N columns. Each of the data lines is commonly connected to the memory cells of a corresponding one of the M rows, where M and N are natural numbers.

### CROSS-REFERENCE TO RELATED APPLICATIONS

This patent application claims priority under 35 U.S.C. § 119 to Korean Patent Application Nos. 10-2023-0044977 filed on Apr. 5, 2023, and 10-2023-0079448 filed on Jun. 21, 2023, respectively, in the Korean Intellectual Property Office, the disclosures of which are incorporated by reference in their entireties herein.

### 1. TECHNICAL FIELD

Embodiments of the present disclosure described herein relate to a multi-bit cell and a multi-bit cell array including the same.

### 2. DISCUSSION OF RELATED ART

A semiconductor chip, also known as an integrated circuit (IC), is a tiny electronic circuit made up of many transistors. The semiconductor chip is made from a semiconductor material, such as silicon, which can conduct electricity under certain conditions. A memory chip is an example of a semiconductor chip that includes transistors arranged in arrays to form memory cells.

The degree of integration of a semiconductor chip refers to the number of transistors that are included thereon. The area occupied by the memory cells may be minimized to increase the degree of integration of a memory chip. A multi-bit cell is a memory cell that can store multiple bits of data. However, when the multi-bit cell is implemented with several sequential logic circuits, arranging the sequential logic circuits in an array form has a large area overhead. Further, since pins of the multi-bit cell are concentrated in a specific area, routing congestion increases.

### SUMMARY

At least one embodiment of the present disclosure provides a multi-bit cell and a multi-bit cell array including the same that can save routing resources and reduce routing congestion.

According to an embodiment of the present disclosure, a multi-bit cell includes a plurality of memory cells arranged in an M×N array having M rows and N columns, a plurality of first clock lines, a plurality of second clock lines, and a plurality of data lines. M and N are natural numbers. Each of the first clock lines is commonly connected to the memory cells of a corresponding one of the N columns. Each of the second clock lines is commonly connected to the memory cells of a corresponding one of the N columns. Each of the data lines is commonly connected to the memory cells of a corresponding one of the M rows.

According to an embodiment of the present disclosure, a multi-bit cell includes a plurality of memory cells arranged in an M×N array having M rows and N columns and plurality of multiplexers. Each of the memory cells of a corresponding one of the M rows is configured to commonly receive input data. Each of the memory cells of a corresponding one of the N columns is configured to commonly receive a clock signal and an inverted clock signal. The plurality of multiplexers are configured to output one output data among output data of each column of the N columns based on a selection signal, and configured to commonly receive the selection signal, M and N are natural numbers.

According to an embodiment of the present disclosure, a multi-bit cell array includes a plurality of multi-bit cells arranged in an M×N array having M rows and N columns and including a plurality of memory cells sequentially connected along a row direction of the M×N array, and a plurality of data lines. Each of the data lines is commonly connected to the plurality of multi-bit cells of a corresponding one of the M rows.

### BRIEF DESCRIPTION OF THE FIGURES

The above and other objects and features of the present disclosure will become apparent by describing in detail embodiments thereof with reference to the accompanying drawings.

FIG. 1 is a circuit diagram of a multi-bit cell according to an embodiment of the present disclosure.

FIG. 2 illustrates an example circuit of a multi-bit cell of FIG. 1.

FIG. 3 illustrates a layout of a multi-bit cell of FIG. 1.

FIG. 4 is a circuit diagram of a multi-bit cell according to an embodiment.

FIG. 5 illustrates a layout of a multi-bit cell of FIG. 4.

FIG. 6 is a circuit diagram of a multi-bit cell according to an embodiment of the present disclosure.

FIG. 7 is a circuit diagram of a multi-bit cell of FIG. 6 as an example.

FIG. 8 illustrates a layout of a multi-bit cell provided with a multiplexer according to an embodiment.

FIG. 9 illustrates pins of a multi-bit cell of FIG. 8.

FIG. 10 illustrates a multi-bit cell array according to an embodiment.

FIG. 11 illustrates a multi-bit cell array according to an embodiment.

FIG. 12 illustrates a memory device according to an embodiment.

FIG. 13 illustrates a processor according to an embodiment.

FIG. 14 illustrates a system according to an embodiment.

### DETAILED DESCRIPTION

Hereinafter, embodiments of the present disclosure are described in detail and clearly to such an extent that one of ordinary skill in the art may implement the present disclosure.

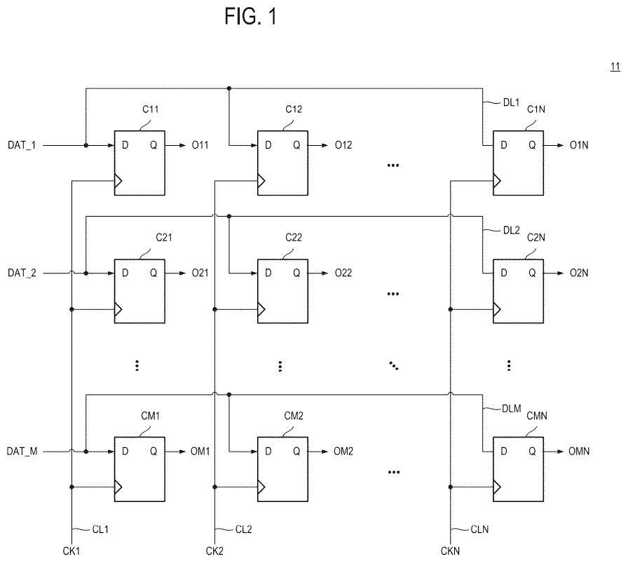

FIG. 1 is a circuit diagram of a multi-bit cell according to an embodiment of the present disclosure.

Referring to FIG. 1, a multi-bit cell 11 according to an embodiment includes a plurality of memory cells C11 to CMN. The plurality of memory cells C11 to CMN may be arranged as an M×N array, where M and N are natural numbers. The array having a size of M×N may store M words and N bits. For example, each of the plurality of memory cells C11 to CMN may be a sequential logic circuit capable of storing and outputting data, such as a latch or a flip-flop. For example, the flip-flop may be a D-type flip-flop, but is not limited thereto.

In an embodiment, the plurality of memory cells C11 to CMN are configured such that input data DAT_1 to DAT_M are commonly applied to each row of the M×N array. In detail, data lines DL1 to DLM may be commonly connected to each row of the plurality of memory cells C11 to CMN. For example, first input data DAT_1 may be commonly applied to the first row of memory cells, second input data DAT_2 may be commonly applied to the second row of memory cells, and M-th input data DAT_M may be commonly applied to the M-th row of memory cells. The plurality of data lines DL1 to DLM may be provided according to the number of rows of the M×N array. The data lines DL1 to DLM may be implemented with metal, for example. When the data lines DL1 to DLM are implemented in metal, one metal line may be commonly connected to each row.

The data lines DL1 to DLM may be connected to data pins included in each of the plurality of memory cells C11 to CMN. In detail, each of the plurality of data lines DL1 to DLM may be commonly connected to data pins included in each row of the M×N array. Accordingly, each row may share data pins with each other through the data lines DL1 to DLM.

For example, the first data line DL1 may be commonly connected to the plurality of memory cells C11 to CIN included in a first row, and the first input data DAT_1 may be applied through the first data line DL1. As in the above description, the M-th data line DLM is commonly connected to the plurality of memory cells CM1 to CMN included in an M-th row, and the M-th input data DAT_M may be applied through the M-th data line DLM.

Each input data DAT_1 to DAT_M applied through each data line DL1 to DLM may correspond to one word. Since N memory cells are included in each row, one word may include N bits.

In an embodiment, the plurality of memory cells C11 to CMN are configured such that clock signals CK1 to CKN are commonly applied to each column of the M×N array. In detail, clock lines CL1 to CLN may be commonly connected to each column of the plurality of memory cells C11 to CMN. For example, a first clock signal CK1 may be applied to a first column of the memory cells, a second clock signal CK2 may be applied to a second column of the memory cells, and a N-th clock signal may be applied to an N-th column of the memory cells. The plurality of clock lines CL1 to CLN may be provided according to the number of columns of the M×N array.

The clock lines CL1 to CLN may be connected to clock pins included in each of the plurality of memory cells C11 to CMN. In detail, each of the plurality of clock lines CL1 to CLN may be configured to be commonly connected to clock pins included in each column of the M×N array. Therefore, each column may share clock pins with each other through clock lines CL1 to CLN.

For example, the first clock line CL1 is commonly connected to the plurality of memory cells C11 to CM1 included in a first column, and the first clock signal CK1 may be applied through the first clock line CL1. As in the above description, the N-th clock line CLN may be commonly connected to a plurality of memory cells C1N to CMN included in an N-th column, and the N-th clock signal CKN may be applied through the N-th clock line CLN.

According to an embodiment, when each of the plurality of memory cells C11 to CMN includes a transistor to which a clock pin is connected and to which the clock signals CK1 to CKN are applied, the clock lines CL1 to CLN may be commonly connected to gates of transistors of the plurality of memory cells C11 to CMN included in each column. For example, when gates are implemented with metal or poly-silicon, the clock lines CL1 to CLN may also be implemented with metal or poly-silicon.

The multi-bit cell 11 having the M×N array may receive M words from the M data lines DL1 to DLM and may store the M received words in each row. Each of the memory cells included in each row may store one of N bits included in one word based on clock signals CK1 to CKN. For example, memory cells included in the M-th row may store bits included in a word corresponding to the M-th input data DAT_M based on the first to N-th clock signals CK1 to CKN.

The memory cells included in each row may output input data of the next state as output data O11 to OMN at rising or falling edges of respective clock signals CK1 to CKN. The output data O11 to OMN may be 1 bit. Any one of the output data O11 to OMN included in each column may be selected and output through a multiplexer (mux) to be described below.

According to the above-described embodiments, eventually, the first input data to the M-th input data DAT_1 to DAT_M may be commonly routed to rows corresponding to each. As a resource for routing the input data DAT_1 to DAT_M, from the viewpoint of the multi-bit cell 11, only M input pins are required to receive the first input data to the M-th input data DAT_1 to DAT_M. In addition, since each row shares the data lines DL1 to DLM, resources used for the data lines DL1 to DLM may also be reduced. Therefore, the multi-bit cell 11 of the present disclosure may reduce the number of input pins for routing the multi-bit cell 11 through the data lines DL1 to DLM commonly connected to each row and resources used for the data lines DL1 to DLM.

In addition, according to the above-described embodiments, the first clock signal to the N-th clock signal CK1 to CKN may be commonly routed to corresponding columns. As a resource for routing the clock signals CK1 to CKN, from the viewpoint of the multi-bit cell 11, only N clock pins are required to receive the first clock signal to the N clock signal CK1 to CKN. Since each column shares the clock lines CL1 to CLN, the resources used for the clock lines CL1 to CLN may also be reduced. Therefore, the multi-bit cell 11 of the present disclosure may reduce the number of clock pins for routing the multi-bit cell 11 through the clock lines CL1 to CLN commonly connected to each column and resources used for the clock lines CL1 to CLN. In addition, power consumption of multi-bit cells may be reduced according to the reduced use of resources.

As a result, the multi-bit cell 11 of the present disclosure may use less resources for routing the input data DAT_1 to DAT_M and the clock signals CK1 to CKN, and may have reduced routing congestion with respect to pins and power consumption at the chip level where the multi-bit cell 11 is used.

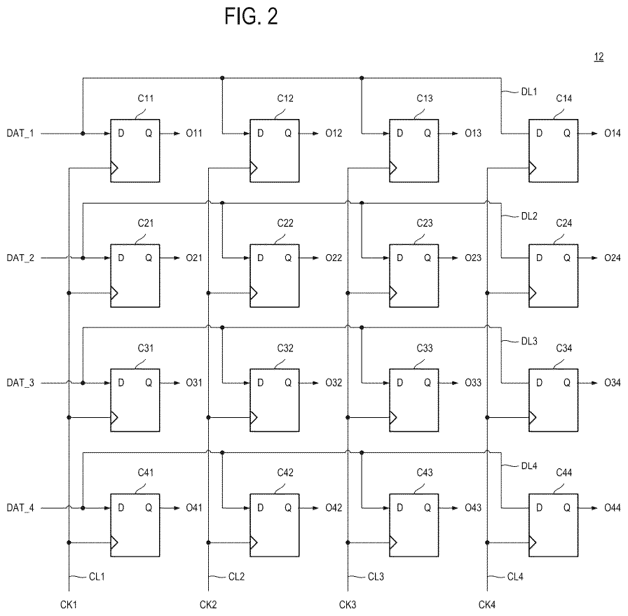

FIG. 2 illustrates an example circuit of the multi-bit cell of FIG. 1.

Referring to FIG. 2, a multi-bit cell 12 according to an embodiment may include 16 memory cells. The plurality of memory cells C11 to C44 may be configured to have a 4×4 array.

In an embodiment, the plurality of memory cells C11 to C44 are configured such that input data DAT_1 to DAT_4 are commonly applied to each row of the 4×4 array. In detail, data lines DL1 to DL4 may be commonly connected to each row of the plurality of memory cells C11 to C44. Accordingly, four data lines DL1 to DL4 may be provided.

For example, the first data line DL1 is commonly connected to the memory cells C11 to C14 corresponding to a first row to receive the first input data DAT_1, the second data line DL2 is commonly connected to the memory cells C21 to C24 corresponding to a second row to receive the second input data DAT_2, the third data line DL3 is commonly connected to the memory cells C31 to C34 corresponding to a third row to receive third input data DAT_3, and the fourth data line DL4 is commonly connected to the memory cells C41 to C44 corresponding to a fourth row to receive fourth input data DAT_4.

The data lines DL1 to DL4 may be connected to data pins included in each of the 16 memory cells C11 to C44. Accordingly, each row may share four data pins through the data lines DL1 to DL4.

In an embodiment, the plurality of memory cells C11 to C44 are configured such that clock signals CK1 to CK4 are commonly applied to each column of the 4×4 array. In detail, the clock lines CL1 to CL4 may be commonly connected to each column of the plurality of memory cells C11 to C44. Accordingly, the four clock lines CL1 to CL4 may be provided.

For example, the first clock line CL1 is commonly connected to the memory cells C11 to C41 corresponding to a first column to receive the first clock signal CK1, the second clock line CL2 is commonly connected to memory cells C12 to C42 corresponding to a second column to receive the second clock signal CK2, the third clock line CL3 is commonly connected to the memory cells C13 to C43 corresponding to a third column to receive the third clock signal CK3, and the fourth clock line CL4 is commonly connected to the memory cells C14 to C44 corresponding to a fourth column to receive the fourth clock signal CK4.

The clock lines CL1 to CL4 may be connected to clock pins included in each of the 16 memory cells C11 to C44. Therefore, each column may share four clock pins through the clock lines CL1 to CL4.

The 16-bit multi-bit cell 12 may receive four words from the four data lines DL1 to DL4 and may store the received 4 words in each row. For example, each row may store a different one of the 4 words. Each of the memory cells included in each row may store one of four bits included in one word. The memory cells included in each row may store one word based on the first to fourth clock signals CK1 to CK4. For example, the memory cells C11 to C14 included in the first row may store a word corresponding to the first input data DAT_1.

In addition, any one of the output data O11 to O44 of the memory cells included in each column may be selected through a multiplexer to be described below. For example, any one of the 1-1st output data O11 to 4-1st output data O41 output from the memory cells C11 to C41 included in the first column may be selected.

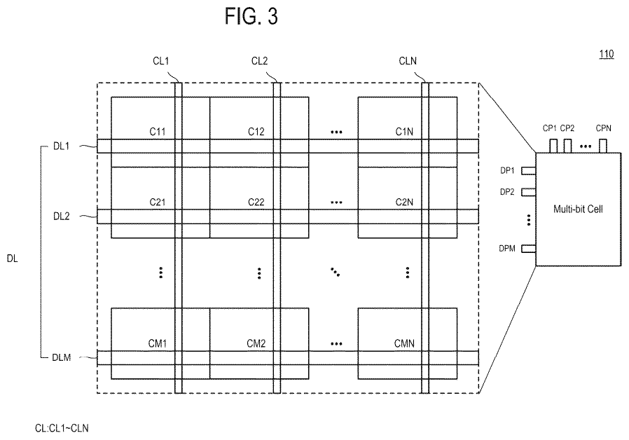

FIG. 3 illustrates a layout of a multi-bit cell of FIG. 1 according to an embodiment.

Referring to FIG. 3, a multi-bit cell 110 according to an embodiment includes the plurality of memory cells C11 to CMN, a plurality of data lines DL, and a plurality of clock lines CL, as described above.

The plurality of data lines DL, that is, each of the first to M-th data lines DL1 to DLM may be arranged in each row of the plurality of memory cells C11 to CMN having an M×N array. In addition, the plurality of clock lines CL, that is, the first to N-th clock lines CL1 to CLN may be arranged in each column of the plurality of memory cells C11 to CMN.

For example, when each data line DL is implemented with metal, one metal line may be commonly arranged in one row. In addition, when each clock line CL is implemented with polysilicon, one polysilicon line may be commonly arranged in one column. In detail, the gates of the transistors included in each column may be connected with the same polysilicon.

Each memory cell C11 to CMN may include a data pin to which input data is applied and a clock pin to which a clock signal is applied, and the data pins included in each row may be shared through the data lines DL arranged in each row. In addition, clock pins included in each column may be shared through clock lines CL arranged in each column.

According to an embodiment of the present disclosure, from the point of view of the multi-bit cell 110, only M data pins DP1 to DPM and N clock pins CP1 to CPN are required. Accordingly, resources for routing may be reduced and routing congestion for pins may be reduced. For example, the multi-bit cell 110 may include a first data pin DP1 for providing data to memory cells C11, C12, . . . , C1N; a second data pin for providing data to memory cells C21, C22, . . . , C2N; and an M-th data pin for providing data to memory cells CM1, CM2, . . . , CMN. For example, the multi-bit cell 110 may include a first clock pin CP1 for providing a clock signal to memory cells C11, C21, . . . , CM1; a second clock pin CP2 for providing a clock signal to memory cells C12, C22, . . . , CM2; and an N-th clock pin CPN for providing a clock signal to memory cells C1N, C2N, . . . , CMN.

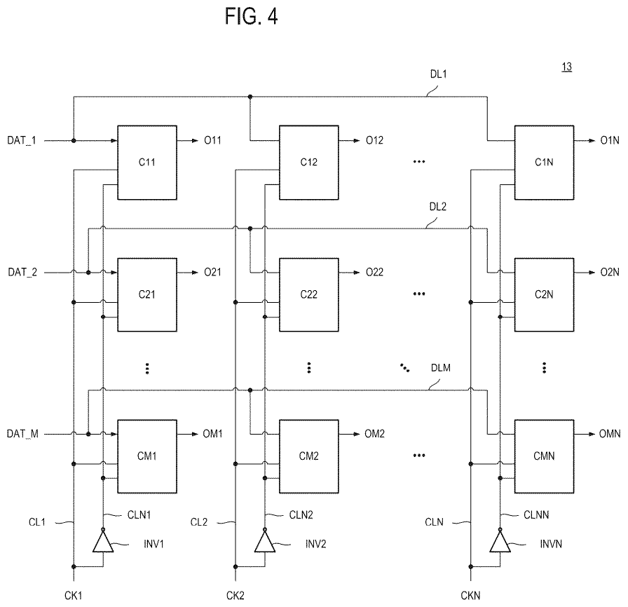

FIG. 4 is a circuit diagram of a multi-bit cell according to an embodiment. Hereinafter, additional descriptions of overlapping contents with the above contents will be omitted to avoid redundancy.

Referring to FIG. 4, a multi-bit cell 13 according to an embodiment may further include a plurality of clock inverters INV1 to INVN and a plurality of inverted clock lines CLN1 to CLNN in addition to the plurality of memory cells C11 to CMN, the plurality of data lines DL1 to DLM, and the plurality of clock lines CL1 to CLN.

The plurality of clock inverters INV1 to INVN may apply an inverted clock signal obtained by inverting the clock signal CK1 to CKN through the plurality of inverted clock lines CLN1 to CLNN to each memory cell C11 to CMN. The plurality of clock inverters INV1 to INVN may be provided as many as the number of columns of the M×N array, for example, N clock inverters may be provided. Each of the clock inverters may be implemented by an inverter circuit.

The inverted clock lines CLN1 to CLNN may be connected to inverted clock pins included in each of the plurality of memory cells C11 to CMN. In detail, each of the plurality of inverted clock lines CLN1 to CLNN may be configured to be commonly connected to inverted clock pins included in each column of the M×N array. Therefore, each column may share inverted clock pins with each other through the inverted clock lines CLN1 to CLNN. In an embodiment, each memory cell of FIG. 4 includes two clock terminals, one for receiving a clock signal and another for receiving an inverted clock signal.

For example, the first inverted clock line CLN1 is commonly connected to the plurality of memory cells C11 to CM1 included in the first column, and a first inverted clock signal may be applied through the first inverted clock line CLN1. As in the above description, the N-th inverted clock line CLNN may be commonly connected to the plurality of memory cells C1N to CMN included in the N-th column, and an N-th inverted clock signal may be applied through the N-th inverted clock line CLNN.

Similar to the clock pins, the inverted clock lines CLN1 to CLNN may also be commonly connected to gates of transistors of the plurality of memory cells C11 to CMN included in each column. For example, the inverted clock lines CLN1 to CLNN may be implemented with metal or polysilicon.

For example, when each memory cell C11 to CMN includes a plurality of latches (e.g., a master latch and a slave latch), the inverted clock line CLN1 to CLNN may be applied to one of the plurality of latches. Alternatively, in addition, the inverted clock lines CLN1 to CLNN may be implemented in various ways such that the memory cells C11 to CMN may store bits.

The plurality of memory cells C11 to CMN may store the first to M-th input data DAT_1 to DAT_M based on the clock signals CK1 to CKN and the inverted clock signals.

The memory cells C11 to CMN included in each row may output input data in the next state as output data at rising or falling edges of the respective clock signals CK1 to CKN and/or the inverted clock signals.

According to the above-described embodiments, the first inverted clock signal to the N-th inverted clock signal may be commonly routed to the respective corresponding columns. Since the inverted clock signal is generated from the clock signals CK1 to CKN through the plurality of clock inverters INV1 to INVN, only N clock pins are required for routing from the point of view of the multi-bit cell 13. For example, the input of the first clock inverter INV1 and clock terminals of the memory cells of a first column may be connected to a single pin among the N clock pins. Accordingly, resources for routing may be reduced and routing congestion may be reduced.

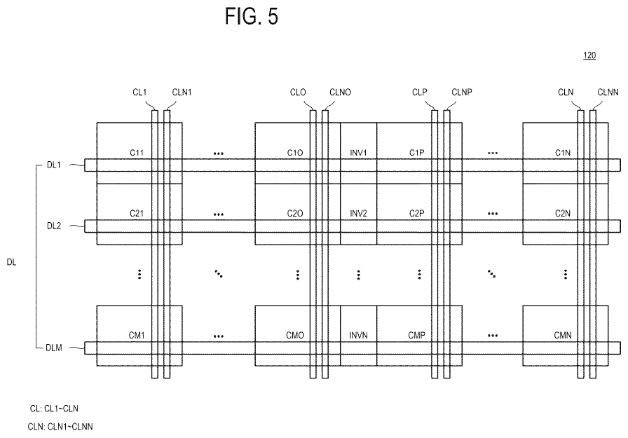

FIG. 5 illustrates a layout of the multi-bit cell of FIG. 4 according to an embodiment.

Referring to FIG. 5, a multi-bit cell 120 according to an embodiment includes the plurality of memory cells C11 to CMN, the plurality of data lines DL, the plurality of clock lines CL, and the plurality of inverted clock lines CLN.

The plurality of data lines DL are arranged in each row of the plurality of memory cells C11 to CMN. The plurality of clock lines CL and the plurality of inverted clock lines CLN are arranged in each column of the plurality of memory cells C11 to CMN. In detail, one clock line CL and one inverted clock line may be commonly arranged in the memory cells C11 to CMN included in one column. For example, one clock line CL and one inverted clock line may overlap one column of the memory cells C11 to CMN.

Among the transistors included in each column, the gate of a first transistor to which the clock line CL is connected is connected to the same polysilicon, and the gate of a second transistor to which the inverted clock line CLN is connected may also be connected with the same polysilicon.

Each memory cell C11 to CMN may include a data pin to which input data is applied and a clock pin to which a clock signal is applied, and the data pins included in each row may be shared through the data lines DL arranged in each row. In an embodiment, each memory cell C11 to CMN further includes an inverted clock pin to which an inverted clock signal is applied. In addition, the clock pins and inverted clock pins included in each column may be shared through the clock line CL and the inverted clock line CLN arranged in each column. Since the inverted clock signal is generated from the clock signal through the clock inverters INV1 to INVN, only N clock pins are required from the point of view of the multi-bit cell 120.

In an embodiment, the plurality of clock inverters INV1 to INVN are provided between an O-th column and a P-th column (where O and P are natural numbers) of the M×N array. In other words, each of the clock inverters INV1 to INVN may be arranged between one memory cell C11 to CMN included in the O-th column and one memory cell C11 to CMN included in the P-th column. The arranged plurality of clock inverters INV1 to INVN may apply the inverted clock signal through the inverted clock line CLN.

For example, the first clock inverter INV1 may apply a first inverted clock signal through the first inverted clock line CLN1, and the N-th clock inverter INVN may apply an N-th inverted clock signal through the N-th inverted clock line CLNN. FIG. 5 illustrates that when M=N as an example, that is, the number of the clock inverters INV1 to INVN and the number of memory cells C11 to CMN arranged in one column are the same, but embodiments of the present disclosure are not limited to thereto. Even if M is different from N, the clock inverters INV1 to INVN may be configured to be arranged between the O-th column and the P-th column.

In an embodiment, when N is an even number, the O-th column and the P-th column may be (N/2) and (N/2)+1 columns, respectively. Alternatively, when N is an odd number, the O-th column and the P-th column may be (N−1)/2 and (N+1)/2 columns, respectively. In this case, a first array including the first to O-th columns of the M×N array and a second array including the P-th to N-th columns may have the same array size. Accordingly, the plurality of inverters INV1 to INVN arranged between the O-th column and the P-th column may apply the inverted clock signal through a minimal routing path.

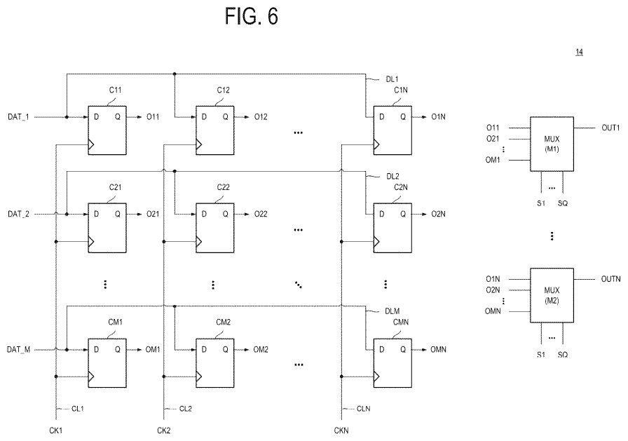

FIG. 6 is a circuit diagram of a multi-bit cell according to an embodiment of the present disclosure.

Referring to FIG. 6, a multi-bit cell 14 according to an embodiment includes one or more muxes M1 and M2 in addition to the plurality of memory cells C11 to CMN, the plurality of data lines DL1 to DLM, and the plurality of clock lines CL1 to CLN.

The one or more muxes M1 and M2 may be configured to select the output data O11 to OMN of the plurality of memory cells C11 to CMN based on selection signals S1 to SQ. The one or more muxes M1 and M2 may select one of the output data O11 to OMN of the memory cells C11 to CMN included in each column. For example, the first mux M1 may select one piece of output data OUT1 from the 1-1 output data to the (M-1)-th output data O11 to OM1), based on the first to Q selection signals S1 to SQ (where Q is a natural number), and the second mux M2 may select one piece of output data OUT2 from the (1-N)-th output data to the (M-N)-th output data O1N to OMN. For example, the number of the selection signals S1 to SQ, that is, Q may have a relationship of M=2^{Q}. For example, a mux may be present for each column that is configured to output data from any one of the memory cells of the corresponding column.

The one piece of output data selected from the one or more muxes M1 and M2 becomes a final output of the multi-bit cell 14. Accordingly, each of the one or more muxes M1 and M2 may correspond to an output pin of the multi-bit cell 14.

In an embodiment, the one or more muxes M1 and M2 all use the same selection signals S1 to SQ. For example, the first mux M1 may output a bit corresponding to any one column among bits included in a word corresponding to a first row, and the second mux M2 may output a bit corresponding to a column selected by the first mux M1 from among bits including a word corresponding to the N-th row.

According to the above-described embodiments, the multi-bit cell 14 of the present disclosure may be implemented with the muxes M1 and M2 integrated therein. When the muxes M1 and M2 are implemented externally, the number of output pins of the multi-bit cell 14 may be provided by as many as the number of memory cells C11 to CMN, but the embodiment of FIG. 6 only provides the number of output pins corresponding to the number of muxes M1 and M2. Accordingly, the multi-bit cell 14 may have less output pins than the multi-bit cell 13.

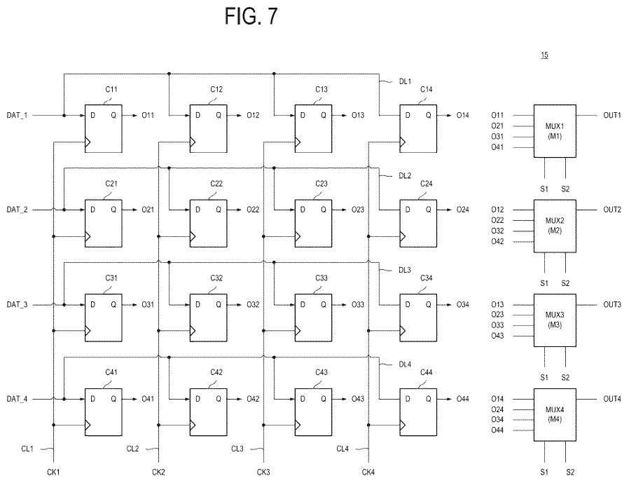

FIG. 7 is a circuit diagram of the multi-bit cell of FIG. 6 as an example.

Referring to FIG. 7, a multi-bit cell 15 according to an embodiment may include 16 memory cells C11 to C44 and 4 muxes M1 to M4, and the plurality of memory cells C11 to C44 may be configured to have the 4×4 array.

The plurality of memory cells C11 to C44 may commonly receive the input data DAT_1 to DAT_4 for each row through the four data lines DL1 to DL4, and may commonly receive the clock signals CK1 to CK4 for each column through the four clock lines CL1 to CL4.

The four muxes M1 to M4 may select one of the output data O11 to O44 of each column based on the two selection signals S1 and S2. For example, the first mux M1 may select one of the output data O11 to O41 corresponding to the first bit in a word corresponding to the first to fourth input data DAT_1 to DAT_4, and the second mux M2 may select one of the output data O12 to O42 corresponding to the second bit in the word corresponding to the first to fourth input data DAT_1 to DAT_4, the third mux M3 may select one of the output data O13 to O43 corresponding to the third bit in the word corresponding to the first to fourth input data DAT_1 to DAT_4, and the fourth mux M4 may select one of the output data O14 to O44 corresponding to the fourth bit in the word corresponding to the first to fourth input data DAT_1 to DAT_4.

In this case, all of the first to fourth muxes M1 to M4 may select the output data O11 to O44 based on the first selection signal S1 and the second selection signal S2, which are the same selection signals S1 and S2. For example, the first to fourth muxes M1 to M4 may select bits of the same order in each word.

Although the clock inverter is omitted in the embodiments of FIGS. 6 and 7, a clock inverter for applying an inverted clock signal may be provided together with the muxes M1 to M4.

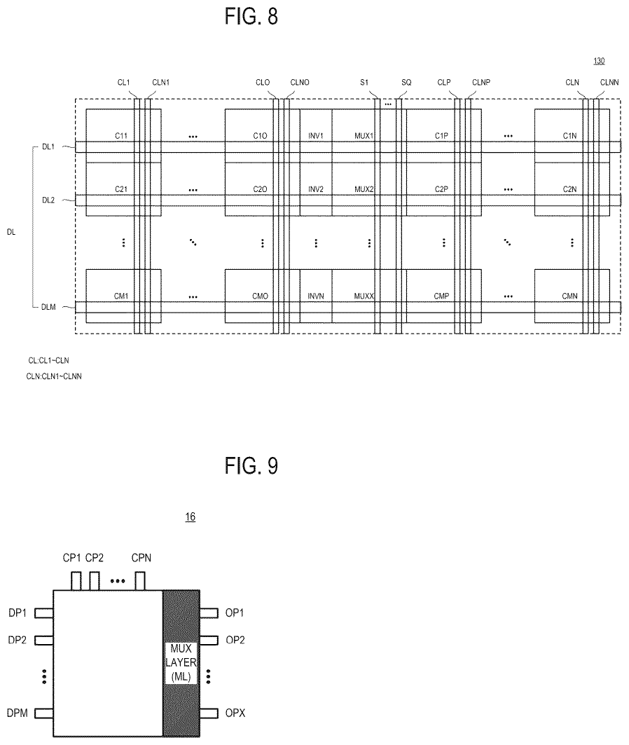

FIG. 8 illustrates a layout of a multi-bit cell provided with a mux according to an embodiment.

Referring to FIG. 8, a multi-bit cell 130 according to an embodiment includes a plurality of muxes MUX1 to MUXX in addition to the plurality of memory cells C11 to CMN, the plurality of data lines DL, the plurality of clock lines CL, and the plurality of inverted clock lines CLN.

The plurality of data lines DL are arranged in each row of the plurality of memory cells C11 to CMN, and the plurality of clock lines CL and the plurality of inverted clock lines CLN are arranged in each column of the plurality of memory cells C11 to CMN. In addition, a plurality of clock inverters INV1 to INVM may be arranged between the 0-th column and the P-th column.

In an embodiment, the plurality of muxes MUX1 to MUXX are disposed between the O-th column and the P-th column of the M×N array, like the plurality of clock inverters INV1 to INVM. In other words, each of the muxes MUX1 to MUXX may be arranged along a column direction between one memory cell included in the O-th column and one memory cell included in the P-th column. Accordingly, the plurality of muxes MUX1 to MUXX arranged between the O-th column and the P-th column may receive outputs of the memory cells C11 to CMN of each column through a minimal routing path.

The plurality of arranged muxes MUX1 to MUXX may receive selection signals through a plurality of selection signal lines S1 to SQ. The plurality of selection signal lines S1 to SQ may be disposed in the plurality of muxes MUX1 to MUXX along the column direction of the M×N array. Accordingly, the plurality of selection signal lines S1 to SQ may all be shared by the plurality of muxes MUX1 to MUXX, so that the selection signals may be commonly applied to each of the plurality of muxes MUX1 to MUXX. According to an embodiment, when each of the plurality of muxes MUX1 to MUXX includes a transistor to which a selection signal is applied, the selection signal lines S1 to SQ may be commonly connected to the gates of transistors of the plurality of memory cells C11 to CMN included in each column. For example, when the gate is implemented with metal or polysilicon, the selection signal lines S1 to SQ may also be implemented with metal or polysilicon.

For example, the first mux MUX1 may select and output first selection data based on selection signals applied from the plurality of selection signal lines S1 to SQ, the second mux MUX2 may select and output second selection data based on the same selection signals, and the X-th mux MUXX may select and output X-th selection data based on the same selection signals.

Although FIG. 8 illustrates that the number of muxes MUX1 to MUXX and memory cells C11 to CMN are the same as each other, even if the numbers are different from each other, the muxes MUX1 to MUXX may be configured to be arranged between the O-th and P-th columns. While a mux may be present for each row of the memory cells C11 to CMN, embodiments of the disclosure are not limited thereto.

According to at least one of the above-described embodiments, the multi-bit cell 130 of the present disclosure will eventually have X pieces of selection data (where ‘X’ is a natural number) corresponding to the plurality of muxes MUX1 to MUXX as outputs. Therefore, since the multi-bit cell 130 has only as many output pins as the number of muxes MUX1 to MUXX by including the muxes MUX1 to MUXX therein, the number of pins may be reduced.

In addition, when the plurality of muxes MUX1 to MUXX are provided outside the multi-bit cell 130, a device isolation layer implemented through a Shallow Trench Isolation (STI) process for the multi-bit cell 130 and a device isolation layer for stages of the muxes MUX1 to MUXX may be provided separately. However, in an embodiment of the present disclosure, when the plurality of muxes MUX1 to MUXX are integrated inside the multi-bit cell 130, the number of the device isolation layer is reduced compared to the case where they are provided externally, and thus an area of the multi-bit cell 130 may be decreased.

FIG. 9 illustrates pins of a multi-bit cell of FIG. 8 according to an embodiment.

Referring to FIG. 9, a multi-bit cell 16 according to an embodiment includes a first data pin to an M-th data pin DP1 to DPM, a first clock pin to an N-th clock pin CP1 to CPN, and a first output pin to an X-th output pin OP1 to OPX.

As described above, the multi-bit cell 16 has only the M data pins DP1 to DPM and the N clock pins CP1 to CPN due to the select lines shared by each row and the clock lines shared by each column. In addition, since a mux layer ML is included inside the multi-bit cell 16, the output pins OP1 to OPX may be provided as many as the number (e.g., X, which is a natural number) of muxes. The mux layer ML may include the plurality of muxes described above, and output ends of the plurality of muxes may be connected to the respective output pins OP1 to OPX.

When the mux layer ML is provided at the output ends or on a boundary perimeter of the multi-bit cell 16, an area of the device isolation layer for the multi-bit cell 16 may be reduced. In addition, when the mux layer ML is provided externally, the multi-bit cell 16 may require an additional inverter for filtering an external signal. However, according to an embodiment of the present disclosure, when the mux layer ML is provided in the output ends inside the multi-bit cell 16, an additional inverter is not required. Accordingly, the multi-bit cell 16 of the present disclosure may have a reduced area. In addition, when an additional inverter is provided, a signal eventually has to pass through both the inverter and the mux, but in an embodiment of the present disclosure, when the mux layer ML is provided therein, there is no need for the inverter, thereby reducing a signal delay.

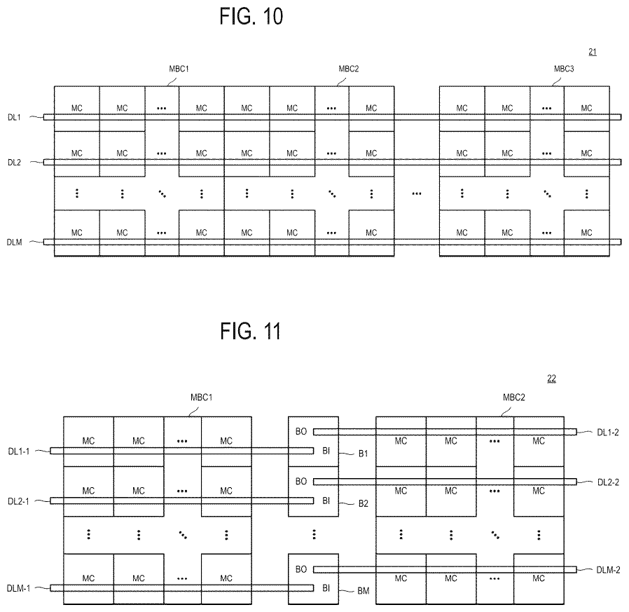

FIG. 10 illustrates a multi-bit cell array according to an embodiment.

Referring to FIG. 10, a multi-bit cell (MBC1 to MBC3) array 21 may include a plurality of multi-bit cells MBC1 to MBC3 implemented according to the above-described embodiments. The multi-bit cells MBC1 to MBC3 may be arranged in various directions in addition to being sequentially connected along the row direction of the M×N array through a Place and Route (PnR) as illustrated in FIG. 10. Each of the multi-bit cells MBC1 to MBC3 is capable of storing more than one bit of data.

Each of the plurality of multi-bit cells MBC1 to MBC3 may include a plurality of memory cells MC having the M×N array.

Each of the plurality of data lines DL1 to DLM may be commonly arranged in each row of the multi-bit cell (MBC1 to MBC3) array 21. In addition, although not illustrated in FIG. 10, each of the multi-bit cells MBC1 to MBC3 may include at least one of a clock line, an inverted clock line, and a selection signal line commonly arranged in each column according to various embodiments and may include a clock inverter for applying an inverted clock signal and/or a mux for selecting output data.

In detail, as the plurality of data lines DL1 to DLM are commonly arranged in each row of the multi-bit cell (MBC1 to MBC3) array 21, all of the multi-bit cells MBC1 to MBC3 may share the plurality of data lines DL1 to DLM in units of rows. Accordingly, the data pins of each of the multi-bit cells MBC1 to MBC3 may also be shared.

According to the above-described embodiments, the multi-bit cell (MBC1 to MBC3) array 21 of the present disclosure may minimize routing of input data through the data lines DL1 to DLM and the data pins shared among the multi-bit cells MBC1 to MBC3.

FIG. 11 illustrates a multi-bit cell array according to an embodiment.

Referring to FIG. 11, a multi-bit cell array 22 may further include a plurality of buffers B1 to BM (e.g., buffer circuits) in addition to the plurality of multi-bit cells MBC1 and MBC2 included in FIG. 10.

The plurality of buffers B1 to BM may be disposed between any two multi-bit cells MBC1 and MBC2 among the plurality of multi-bit cells MBC1 and MBC2. For example, the plurality of buffers B1 to BM may be arranged along a column direction between two multi-bit cells MBC1 and MBC2. For example, the plurality of buffers B1 to BM may be provided as many as M, which is the number of rows of the M×N array.

An input end of each buffer B1 to BM is connected to an output end of the first multi-bit cell MBC1, and an output end of each buffer B1 to BM is connected to an input end of the second multi-bit cell MBC2. Each of the buffers B1 to BM may receive an output (e.g., output data selected from a plurality of muxes) of the first multi-bit cell MBC1 as input data BI of the buffers B1 to BM to buffer the received output, and may apply buffered data BO as input data of the second multi-bit cell MBC2. Accordingly, loss or distortion that may occur in input data routed between the multi-bit cells MBC1 and MBC2 may be compensated. The plurality of buffers B1 to BM may be arranged in the plurality of multi-bit cell arrays 22 in consideration of the routing path. In an embodiment, the plurality of buffers B1 to BM are arranged appropriately in areas where loss or distortion of input data increases according to routing.

In an embodiment, any two multi-bit cells MBC1 and MBC2 sandwiching or adjacent to the plurality of buffers B1 to BM may be configured to be opposite to each other based on the row direction of the plurality of multi-bit cells MBC1 and MBC2. For example, the first multi-bit cell MBC1 and the second multi-bit cell MBC2 may have structures that are symmetrical to each other in a row direction. Accordingly, a plurality of first data lines DL1-1 to DLM-1 arranged in the first multi-bit cell MBC1 and a plurality of second data lines DL1-2 to DLM-2 arranged in the second multi-bit cell MBC2 may be configured to be symmetrical to each other in terms of the buffers B1 to BM. In addition, not only the data lines, but also components (e.g., memory cells MC) included in each of the multi-bit cells MBC1 and MBC2 may be configured to be symmetrical to each other with respect to the row direction.

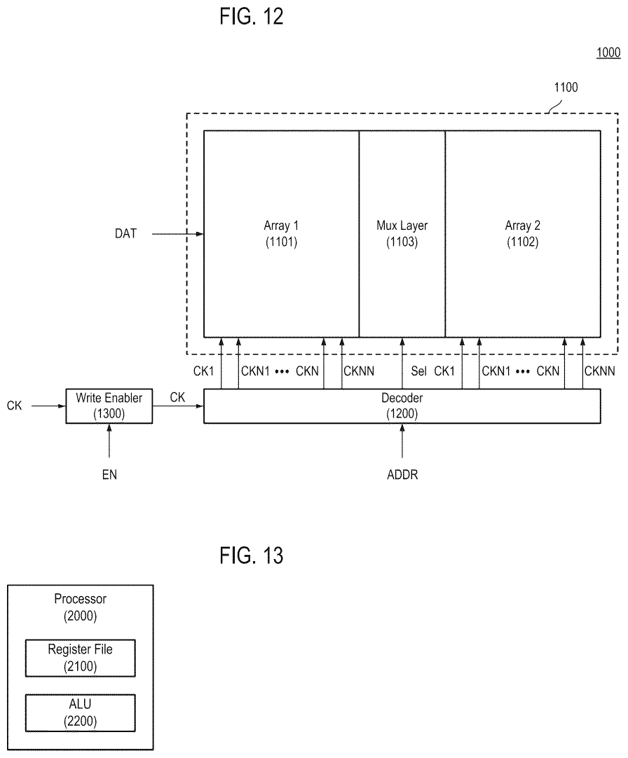

FIG. 12 illustrates a memory device according to an embodiment.

Referring to FIG. 12, a memory device 1000 according to an embodiment includes a memory cell array 1100, a decoder 1200, and a write enabler 1300 (e.g., a write enabler circuit).

The memory cell array 1100 may be implemented using a multi-bit cell or the multi-bit cell array 22 according to the above-described embodiments. The memory cell array 1100 may receive the input data DAT and may store M words and N bits. In this case, the input data DAT may be commonly applied to each row of a first array 1101 and a second array 1102 of the memory cell array 1100. The memory cell array 1100 may include M rows and N columns. The memory cell array 1100 may store write data based on a clock signal.

The decoder 1200 (e.g., a decoder circuit) may receive and decode address information ADDR to generate decoded address information. The decoder 1200 may apply the clock signals CK1 to CKN and the inverted clock signals CKN1 to CKNN to the memory cell array 1100 based on the decoded address information. In this case, the clock signals CK1 to CKN and the inverted clock signals CKN1 to CKNN may be commonly applied to each column of the memory cell array 1100. The write enabler 1300 may transfer the clock signal CK to the decoder 1200 based on an enable signal EN.

In addition, the decoder 1200 may transmit a selection signal Sel to a mux layer 1103 provided between the first array 1101 and the second array 1102 based on the decoded address information. In this case, the selection signal Sel may be commonly applied to all muxes included in the mux layer 1103.

FIG. 13 illustrates a processor according to an embodiment.

Referring to FIG. 13, a processor 2000 may be implemented as a general-purpose processor, a dedicated processor, an application processor (AP), etc. For example, the processor may be implemented as an operation processor (e.g., a central processing unit (CPU)) including a dedicated logic circuit (e.g., a field programmable gate array (FPGA), application specific integrated circuits (ASICs), etc., a GPU (Graphics Processing Unit), etc., but is not limited thereto.

The processor 2000 may execute programs and process data in response to a clock signal. The processor 2000 according to an embodiment may include a register file 2100 and an arithmetic logic unit (ALU) 2200.

The register file 2100 may be implemented through a multi-bit cell or a multi-bit cell array according to the above-described embodiments. The register file 2100 may store M words and N bits. The register file 2100 may store temporary data and operands. The register file 2100 may provide fast and low-latency access with respect to stored elements. The register file 2100 may include a read port and a write port for retrieving and storing stored data.

The ALU 2200 may perform arithmetic and logical operations on data. For example, the ALU 2200 may perform operations such as addition, subtraction, multiplication, division, bitwise calculation, and comparisons. The ALU 2200 may receive operands stored in the register file 2100, may perform designated operations, and may output results. The output result may be temporarily stored in the register file 2100 again.

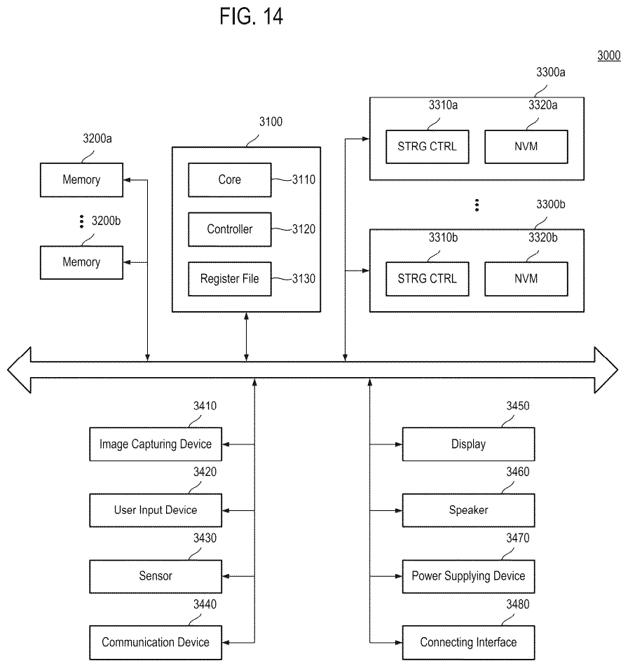

FIG. 14 illustrates a system according to an embodiment.

Referring to FIG. 14, a system 3000 may be a mobile system 3000 such as a mobile phone, a smart phone, a tablet personal computer, a wearable device, a healthcare device, or an Internet Of Things (IOT) device. Alternatively, the system 3000 may be not only a mobile system such as a personal computer, a laptop computer, a server, a media player, or a navigation device, but also an automotive device.

As an embodiment, the system 3000 may include a main processor 3100, memories 3200a to 3200b, and storage devices 3300a and 3300b, and may additionally include an image capturing device 3410, a user input device 3420, a sensor 3430, a communication device 3440, a display 3450, a speaker 3460, a power supplying device 3470, and a connecting interface 3480.

The main processor 3100 may control the overall operation of the system 3000, in more detail, operations of other components included in the system 3000. The main processor 3100 may be implemented as a general-purpose processor, a dedicated processor, or an application processor.

The main processor 3100 may include one or more cores 3110, and may further include a controller 3120 and a register file 3130 for controlling the memories 3200a to 3200b and/or the storage devices 3300a and 3300b. The register file 3130 may be implemented through a multi-bit cell according to the above-described embodiments, as well as the register file of FIG. 13. According to an embodiment, the main processor 3100 may further include an accelerator, which is a dedicated circuit for high-speed data operations such as Artificial Intelligence (AI) data operations.

The memories 3200a to 3200b may be used as main memory devices of the system 3000 and may include non-volatile memories such as an SRAM and/or a DRAM. The memories 3200a to 3200b may be implemented in the same package as the main processor 3100.

The storage devices 3300a and 3300b may function as non-volatile storage devices that store data regardless of whether power is supplied, and may have a relatively large storage capacity compared to a memory. The storage devices 3300a and 3300b may include storage controllers 3310a and 3310b and non-volatile memories (NVMs) 3320a and 3320b that store data under the control of the storage controllers 3310a and 3310b. The NVMs 3320a and 3320b may include a 2D (2-dimensional) structure flash memory or a 3D V-NAND (Vertical NAND) structure flash memory, but may include other types of non-volatile memory such as a PRAM and/or an RRAM.

The storage devices 3300a and 3300b may be included in the system 3000 while being physically separated from the main processor 3100 or may be implemented in the same package as the main processor 3100. In addition, since the storage devices 3300a and 3300b have a form such as a solid state device (SSD) or a memory card, they may be combined to be attached to and to be detached from other components of the system 3000 through an interface such as a connecting interface 3480 to be described later. The storage devices 3300a and 3300b may be devices to which standards such as Universal Flash Storage (UFS), embedded Multi-Media Card (eMCC), or Non-Volatile Memory express (NVMe) are applied, but are not necessarily limited thereto.

The image capturing device 3410 may capture a still image or a video, and may be a camera, camcorder, and/or webcam.

The user input device 3420 may receive various types of data input from a user of the system 3000, and may be a touch pad, keypad, keyboard, mouse, and/or microphone.

The sensor 3430 may sense various types of physical quantities that can be acquired from the outside of the system 3000 and may convert the detected physical quantities into electrical signals. The sensor 3430 may be a temperature sensor, a pressure sensor, an illuminance sensor, a position sensor, an acceleration sensor, a bio sensor, and/or a gyroscope sensor.

The communication device 3440 may transmit and receive signals with other devices outside the system 3000 according to various communication protocols. The communication device 3440 may be implemented by including an antenna, a transceiver, and/or a modem.

The display 3450 and the speaker 3460 may function as output devices that output visual information and auditory information to a user of the system 3000, respectively.

The power supplying device 3470 may appropriately convert power supplied from a battery built into the system 3000 and/or an external power source and may supply the converted power to each component of the system 3000.

The connecting interface 3480 may provide a connection between the system 3000 and an external device that is connected to the system 3000 and can exchange data with the system 3000. The connecting interfaces 3480 may be implemented in various interface methods, such as Advanced Technology Attachment (ATA), Serial ATA (SATA), external SATA (e-SATA), Small Computer Small Interface (SCSI), Serial Attached SCSI (SAS), Peripheral Component Interconnection (PCI), PCIe (PCI express), NVM express (NVMe), IEEE 1394, universal serial bus(USB), secure digital (SD) card, multi-media card (MMC), embedded multi-media card (eMMC), Universal Flash Storage (UFS), embedded universal flash storage (eUFS), and compact flash (CF) card interface.

According to an embodiment of the present disclosure, a multi-bit cell that may save routing resources and reduce routing congestion and a multi-bit cell array including the same may be provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A multi-bit cell comprising:
a plurality of memory cells arranged in an M×N array having M rows and N columns, wherein M and N are natural numbers;
a plurality of first clock lines, where each of the first clock lines is commonly connected to the memory cells of a corresponding one of the N columns;
a plurality of second clock lines, wherein each of the second clock lines is commonly connected to the memory cells of a corresponding one of the N columns; and
a plurality of data lines, where each of the data lines is commonly connected to the memory cells of a corresponding one of the M rows.

2. The multi-bit cell of claim 1, wherein each of the plurality of memory cells is a latch or flip-flop.

3. The multi-bit cell of claim 1, wherein each of the plurality of memory cells includes a data pin, and
wherein each of the plurality of data lines is commonly connected to the data pin included in each row of the M rows.

4. The multi-bit cell of claim 1, wherein each of the plurality of memory cells includes a clock pin, and
wherein each of the plurality of first clock lines is commonly connected to the clock pin included in each column of the N columns.

5. The multi-bit cell of claim 1, wherein a clock signal is applied to the plurality of first clock lines, and
wherein an inverted clock signal of the clock signal is applied to the plurality of second clock lines.

6. The multi-bit cell of claim 5, further comprising:
a plurality of clock inverters disposed between an O-th column and a P-th column of the M×N array, and configured to apply the inverted clock signal to the plurality of second clock lines, wherein O and P are natural numbers.

7. The multi-bit cell of claim 6, wherein a first array including a first column to the O-th column of the M×N array and a second array including the P-th column to N-th column of the M×N array have a same array size.

8. The multi-bit cell of claim 1, further comprising:
a plurality of multiplexers disposed between an O-th column and a P-th column of the M×N array, and configured to output one output data among the output data of each column of the M×N array based on a selection signal, where O and P are natural numbers smaller than N.

9. The multi-bit cell of claim 8, further comprising:
a plurality of selection signal lines arranged along a column direction of the M×N array and configured to commonly apply the selection signal to each of the plurality of multiplexers.

10. The multi-bit cell of claim 8, further comprising:
a plurality of output pins connected to the plurality of multiplexers, each outputting the one output data.

11. A multi-bit cell comprising:
a plurality of memory cells arranged in an M×N array having M rows and N columns, wherein each of the memory cells of a corresponding one of the M rows is configured to commonly receive input data, and each of the memory cells of a corresponding one of the N columns is configured to commonly receive a clock signal and an inverted clock signal; and
a plurality of multiplexers configured to output one output data among output data of each column of the N columns based on a selection signal, and configured to commonly receive the selection signal,
wherein M and N are natural numbers.

12. The multi-bit cell of claim 11, wherein the plurality of multiplexers are disposed between an O-th column and a P-th column of the M×N array, wherein O and P are natural numbers smaller than N.

13. The multi-bit cell of claim 12, wherein the plurality of multiplexers are arranged along a column direction of the M×N array.

14. The multi-bit cell of claim 11, wherein each of the plurality of memory cells is a latch or flip-flop.

15. The multi-bit cell of claim 11, further comprising:
a plurality of clock inverters provided between an O-th column and a P-th column of the M×N array, and configured to apply the inverted clock signal, wherein O and P are natural numbers.

16. A multi-bit cell array comprising:
a plurality of multi-bit cells arranged in an M×N array having M rows and N columns and including a plurality of memory cells sequentially connected along a row direction of the M×N array, wherein M and N are natural numbers; and
a plurality of data lines, where each of the data lines is commonly connected to the plurality of multi-bit cells of a corresponding one of the M rows.

17. The multi-bit cell array of claim 16, further comprising:
a plurality of first clock lines, where each of the first clock lines is commonly connected to the multi-bit cells of a corresponding one of the N columns; and
a plurality of second clock lines, wherein each of the second clock lines is commonly connected to the multi-bit cells of a corresponding one of the N columns.

18. The multi-bit cell array of claim 16, further comprising:
a plurality of buffers disposed between any two multi-bit cells among the plurality of multi-bit cells.

19. The multi-bit cell array of claim 18, wherein the plurality of buffers buffer output data output from one of the two multi-bit cells to generate buffered data and applies the buffered data as input data to the remaining one.

20. The multi-bit cell array of claim 18, wherein the any two multi-bit cells are configured to be inverted with each other based on the row direction of the plurality of multi-bit cells.
